(19) United States
(12) Patent Application Publication
(10) Pub. No.: US 2025/0364246 A1
(43) Pub. Date: Nov. 27, 2025

(54) METHODS OF SELECTIVELY FORMING GROUP III NITRIDE SEMICONDUCTOR REGIONS ON EPITAXIALLY GROWN GROUP III NITRIDE SEMICONDUCTOR LAYER STRUCTURES AND RELATED SEMICONDUCTOR DEVICES

(71) Applicant: MACOM Technology Solutions Holdings, Inc., Lowell, MA (US)

(72) Inventors: Gregg Huascar Jessen, Amherst, NH (US); Doris Cvinar, Pelham, NH (US); Robert Carl Fitch, JR., Tankhannock, PA (US)

(21) Appl. No.: 19/050,634

(22) Filed: Feb. 11, 2025

Related U.S. Application Data
(60) Provisional application No. 63/650,565, filed on May 22, 2024.

(51) Int. Cl. H01L 21/02; H01L 21/306; H03F 3/195

(52) U.S. Cl. CPC H01L 21/02642; H01L 21/0217; H01L 21/02458; H01L 21/0254; H01L 21/02631; H01L 21/30617; H03F 3/195

(57) ABSTRACT

A method of forming a semiconductor device comprises forming an anti-nucleation mask that includes an opening on an upper surface of a Group III nitride semiconductor layer structure, forming a Group III nitride semiconductor region on a portion of the Group III nitride semiconductor layer structure that is exposed by the opening.

### CROSS-REFERENCE TO RELATED APPLICATION

The present application claims priority to U.S. Provisional Application Ser. No. 63/650,565, filed May 22, 2024, the entire content of which is incorporated herein by reference.

### BACKGROUND

The present invention relates to Group III nitride semiconductors and, more particularly, to Group III nitride semiconductor devices that include selectively formed Group III nitride regions, and to methods of making such semiconductor devices.

Wide bandgap semiconductor materials refer to semiconductor materials that have a band-gap of at least 1.4 eV. Wide band-gap semiconductor materials have a number of advantageous characteristics as compared to lower bandgap semiconductor materials (e.g., silicon) including high electric field strength, which results in better RF power handling capabilities, improved power switching, and lower switching losses. In addition, the larger band-gap results in a lower number of intrinsic carriers within the semiconductor material, which means that wide band-gap semiconductor devices can operate at higher temperatures before thermally-activated carriers cause unintentional conductivity in various layers of the device (e.g., in a buffer layer). Wide band-gap semiconductor devices also tend to be more robust than lower band-gap semiconductor devices, with the ability to handle higher temperatures and the like. One widely used class of wide bandgap semiconductor materials are “Group III nitride” semiconductor materials. As used herein, the term “Group III nitride” refers to compound semiconductor materials formed between nitrogen and one or more elements in Group III of the periodic table, usually aluminum (“Al”), gallium (“Ga”), indium (“In”) and/or scandium (“Sc”). The term “Group III nitride” therefore encompasses compound semiconductor material formed of a single Group III element and nitrogen such as, for example, gallium nitride (“GaN”), aluminum nitride (“AlN”) and indium nitride (“InN”), and also encompasses materials that include two or more Group III elements such as aluminum gallium nitride (“AlGaN”), aluminum indium gallium nitride (“AlInGaN”) and the like. Group III nitride semiconductor materials have empirical formulas in which one mole of nitrogen is combined with a total of one mole of the Group III elements.

Light emitting diodes, radio frequency (“RF”) transistor amplifiers, power switches, PIN diodes, heterojunction bipolar junction transistors, resistance temperature detectors, IMPATT diodes, power MOS devices and metal insulating semiconductor field effect transistors are examples of semiconductor devices that are often formed using Group III nitride semiconductor materials. Group III nitride RF transistor amplifiers are typically implemented as High Electron Mobility Transistors (“HEMT”) and are primarily used in applications requiring high power and/or high frequency operation. Group III nitride HEMTs are well suited for operation as RF transistor amplifiers as the high electric field strength of the Group III nitride semiconductor materials allows large voltages to be applied to these devices. Moreover, lateral versions of these devices have relatively high electron mobility, and the heterostructures formed in these devices can have extremely high polarization charge so that the two dimensional electron gas (2DEG) that forms at the heterojunction has both a large number of carriers and relatively high carrier mobility. Group III nitride semiconductor devices include at least one Group III nitride semiconductor layer, but may also include other semiconductor materials such as, for example, silicon carbide or silicon that may be used, for example, as growth substrates, gate electrodes or the like, or that may be embedded in a Group III nitride semiconductor layer structure of the semiconductor device.

Group III nitride semiconductor devices are typically formed via a metal organic chemical vapor deposition (“MOCVD”) epitaxial growth process, although other growth processes or deposition techniques may be used, such as molecular beam epitaxy (“MBE”), atomic layer deposition (“ALD”), chemical vapor deposition (“CVD”) and the like. In a Group III nitride MOCVD growth process, a growth substrate is inserted into a MOCVD growth reactor. The growth substrate typically comprises a silicon carbide, sapphire (Al₂O₃), silicon or GaN substrate, although aluminum nitride (“AlN”) and gallium oxide (“Ga₂O₃”) substrates may also be used, as can any other substrate on which Group III nitride materials may be grown. The growth reactor is heated to a high temperature (e.g., 1000° C.) and very pure precursor gases are injected into the growth reactor, usually along with a non-reactive carrier gas. As the precursor gases approach the growth substrate, the Group III and nitrogen subspecies (e.g., Ga, N, etc.) of the precursor gases combine into the Group III nitride material on the surface of the growth substrate to form one or more thin Group III nitride epitaxial layers on the growth substrate. The Group III nitride epitaxial layers and growth substrate together form a semiconductor layer structure, although it will be appreciated that in some applications the growth substrate may be partly or completely removed after the Group III nitride epitaxial layers are formed so that the semiconductor layer structure may only include the Group III nitride epitaxial layers.

During the MOCVD growth process, additional gases containing dopant atoms may be selectively injected into the growth reactor to dope certain portions of the epitaxial layer structure (i.e., the portions grown when the gases containing dopant atoms are in the reactor) to have n-type or p-type conductivity. This is referred to as doping the semiconductor material during growth, as the dopant atoms are incorporated into the crystal lattice during the formation of the crystal lattice. Layers of semiconductor material that have different constituent elements are considered to be different epitaxial layers, as are layers that have different conductivity types (e.g., p-type layers versus n-type layers). Thus, for example, a thin GaN region in the semiconductor layer structure would be considered to be a different epitaxial layer than an adjacent AlGaN region, and a p-type GaN region would be considered to be a different epitaxial layer than an adjacent n-type GaN region. Adjacent layers of semiconductor material that have the same constituent elements and the same doping type but different doping concentrations may or may not be considered to comprise the same epitaxial layer depending upon the context.

When an MOCVD grown Group III nitride epitaxial layer is doped during growth, the epitaxial layer may be formed to have a constant doping concentration, meaning that the concentration of dopant atoms is relatively constant throughout the thickness of the entire epitaxial layer in the depth direction, or may have a graded doping concentration, meaning that the doping concentration varies as a function of depth (i.e., as a function of the distance from the upper surface of the last of a plurality of epitaxial layers that are grown on the growth substrate). It may be difficult, however, to create an MOCVD epitaxial grown semiconductor layer structure in a commercially practicable manner that has a doping concentration that varies in different regions that are at the same depth within the semiconductor layer structure. Thus, if a semiconductor device requires a semiconductor layer structure that has regions that are at the same depth that have different doping concentrations, these regions are typically formed using ion implantation or by removing selected portions of the semiconductor layer structure and then regrowing semiconductor material having a different doping concentration in the regions where the semiconductor material was removed. Similarly, while different epitaxial layers may have different constituent elements (e.g., a GaN epitaxial layer, an AlGaN epitaxial layer on the GaN epitaxial layer, etc.) or different molar compositions (e.g., Al_{0.1}Ga_{0.9}N, Al_{0.5}Ga_{0.5}N, etc.), a Group III nitride regrowth process is typically used if the semiconductor device needs regions having different constituent elements or molar compositions that are at the same depth within the semiconductor layer structure.

There are various applications where it is desirable to have an MOCVD epitaxial grown semiconductor layer structure that has regions that are at the same depth that have different doping concentrations, different doping types, different molar compositions and/or a different constituent elements. As one example, many Group III nitride RF transistor amplifiers have highly-doped ohmic contact regions that are at the same depth as much lower doped (or undoped) barrier, channel and/or capping layers. In these devices, the ohmic contact regions are typically formed using selective regrowth techniques on top of the Group III nitride semiconductor layer structure or in recesses therein.

### SUMMARY

Pursuant to some embodiments of the present invention, methods of forming a semiconductor device are provided in which an anti-nucleation mask is formed on an upper surface of a Group III nitride semiconductor layer structure. A recess is formed in the upper surface of the Group III nitride semiconductor layer structure. Then, a Group III nitride semiconductor region is formed within the recess without nucleating Group III nitride semiconductor material on an exposed upper surface of the anti-nucleation mask.

In some embodiments, the anti-nucleation mask has an opening, and the recess is formed in a portion of the Group III nitride semiconductor layer structure that is exposed through the opening in the anti-nucleation mask.

In some embodiments, forming the Group III nitride semiconductor region within the recess comprises forming the Group III nitride semiconductor region within the recess by molecular beam epitaxy.

In some embodiments, the anti-nucleation mask comprises an alumina mask.

In some embodiments, the Group III nitride semiconductor region also extends out of the recess so that an upper portion of the Group III nitride semiconductor region is above a plane defined by the upper surface of the Group III nitride semiconductor layer structure.

In some embodiments, the method further comprises forming a dielectric layer on the upper surface of the Group III nitride semiconductor layer structure prior to forming the anti-nucleation mask. In some embodiments, the dielectric layer comprises a silicon nitride layer. In some embodiments, the dielectric layer includes an opening that vertically overlaps the opening in the anti-nucleation mask, and wherein the Group III nitride semiconductor region extends into the opening in the dielectric layer.

In some embodiments, a first portion of the Group III nitride semiconductor region has a first molar composition and horizontally overlaps a portion of the Group III nitride semiconductor layer structure that has a second molar composition that is different from the first molar composition.

In some embodiments, a plurality of gate electrodes, a plurality of drain electrodes and a plurality of source electrodes. In some embodiments, the Group III nitride semiconductor region is positioned underneath and contacts one of drain electrodes or one of the source electrodes. In some embodiments, the Group III nitride semiconductor region comprises at least part of one of the gate electrodes. In some embodiments, the Group III nitride RF transistor amplifier further includes a field plate, and wherein the anti-nucleation mask electrically insulates the field plate from a first of the gate electrodes.

Pursuant to some embodiments of the present invention, methods of forming a Group III nitride RF transistor amplifier are provided that comprise forming an anti-nucleation mask on an upper surface of a Group III nitride semiconductor layer structure, the anti-nucleation mask having an opening, and forming a Group III nitride semiconductor region on a portion of the Group III nitride semiconductor layer structure exposed by the opening in the anti-nucleation mask.

In some embodiments, at least a portion of the Group III nitride semiconductor region is formed within a recess in the upper surface of the Group III nitride semiconductor layer structure.

In some embodiments, the Group III nitride semiconductor region is formed by molecular beam epitaxy.

In some embodiments, an upper surface of the anti-nucleation mask is exposed during the forming of the Group III nitride semiconductor region, and wherein Group III nitride semiconductor material does not nucleate on the anti-nucleation mask during the formation of the Group III nitride semiconductor region.

In some embodiments, the anti-nucleation mask comprises an alumina mask, and an upper surface of the anti-nucleation mask is exposed during the forming of the Group III nitride semiconductor region.

In some embodiments, the method further comprises forming a silicon nitride layer on the upper surface of the Group III nitride semiconductor layer structure prior to forming the anti-nucleation mask. In some embodiments, the silicon nitride layer includes an opening that vertically overlaps the opening in the anti-nucleation mask, and wherein the Group III nitride semiconductor region extends into the opening in the silicon nitride layer.

In some embodiments, a first portion of the Group III nitride semiconductor region has a first molar composition and horizontally overlaps a portion of the Group III nitride semiconductor layer structure that has a second molar composition that is different from the first molar composition.

In some embodiments, the Group III nitride RF transistor amplifier that includes a gate electrode, a drain electrode and a source electrode, and the Group III nitride semiconductor region directly contacts either the drain electrode or the source electrode.

In some embodiments, the Group III nitride semiconductor region comprises at least part of the gate electrode.

In some embodiments, the Group III nitride RF transistor amplifier that includes a gate electrode, a drain electrode, a source electrode and a field plate, and wherein the anti-nucleation mask electrically insulates the field plate from the gate electrode.

In some embodiments, forming the Group III nitride semiconductor region within the recess comprises forming the Group III nitride semiconductor region within the recess in a manner such that Group III nitride semiconductor material does not nucleate on an exposed upper surface of the anti-nucleation mask.

Pursuant to further embodiments of the present invention, RF transistor amplifiers are provided that comprise a Group III nitride semiconductor layer structure having a channel layer and a barrier layer that has a higher bandgap than the channel layer on the channel layer; and an anti-nucleation mask on an upper surface of the Group III nitride semiconductor layer structure, the anti-nucleation mask having an opening that vertically overlaps a portion of the Group III nitride semiconductor layer structure.

In some embodiments, the anti-nucleation mask comprises an alumina mask.

In some embodiments, the RF transistor amplifier further comprises a Group III nitride semiconductor region in a recess in the upper surface of the Group III nitride semiconductor layer structure. In some embodiments, a portion of the Group III nitride semiconductor region and a portion of the Group III nitride semiconductor layer structure that is at a same height above a plane defined by a lower surface of the Group III nitride semiconductor layer structure have different constituent elements.

In some embodiments, the portion of the Group III nitride semiconductor region is GaN or InGaN and the portion of the Group III nitride semiconductor layer structure is AlGaN.

In some embodiments, a portion of the Group III nitride semiconductor region and a portion of the Group III nitride semiconductor layer structure that is at a same height above a plane defined by a lower surface of the Group III nitride semiconductor layer structure have different doping concentrations.

In some embodiments, a portion of the Group III nitride semiconductor region and a portion of the Group III nitride semiconductor layer structure that is at a same height above a plane defined by a lower surface of the Group III nitride semiconductor layer structure have different conductivity types.

In some embodiments, the Group III nitride semiconductor region extends out of the recess so that an upper portion of the Group III nitride semiconductor region is above a plane defined by the upper surface of the Group III nitride semiconductor layer structure.

In some embodiments, the RF transistor amplifier further comprises a silicon nitride layer that is between the upper surface of the Group III nitride semiconductor layer structure and the anti-nucleation mask.

In some embodiments, the Group III nitride RF transistor amplifier further includes a gate electrode, a drain electrode and a source electrode. In some embodiments, the Group III nitride semiconductor region directly contacts either the drain electrode or the source electrode. In some embodiments, the drain electrode is within the opening in the anti-nucleation mask. In some embodiments, the Group III nitride semiconductor region comprises at least part of the gate electrode. In some embodiments, the Group III nitride RF transistor amplifier further includes a field plate, and wherein the anti-nucleation mask electrically insulates the field plate from the gate electrode.

Pursuant to still further embodiments of the present invention, semiconductor devices are provided that comprise a Group III nitride semiconductor layer structure; an anti-nucleation mask on an upper surface of the Group III nitride semiconductor layer structure, the anti-nucleation mask having an opening that exposes the Group III nitride semiconductor layer structure; and a selectively formed Group III nitride semiconductor region on the Group III nitride semiconductor layer structure.

In some embodiments, the anti-nucleation mask comprises an alumina mask.

In some embodiments, an upper surface of the Group III nitride semiconductor layer structure includes a recess, and the Group III nitride semiconductor region is within the recess and extends out of the recess so that an upper portion of the Group III nitride semiconductor region is above a plane defined by the upper surface of the Group III nitride semiconductor layer structure.

In some embodiments, a portion of the Group III nitride semiconductor region and a portion of the Group III nitride semiconductor layer structure that is at a same height above a plane defined by a lower surface of the Group III nitride semiconductor layer structure comprise different constituent elements. In some embodiments, the portion of the Group III nitride semiconductor region is InGaN or GaN and the portion of the Group III nitride semiconductor layer structure is AlGaN.

In some embodiments, a portion of the Group III nitride semiconductor region and a portion of the Group III nitride semiconductor layer structure that is at a same height above a plane defined by a lower surface of the Group III nitride semiconductor layer structure as the first portion of the Group III nitride semiconductor region have different doping concentrations.

In some embodiments, the semiconductor device further comprises a dielectric layer that is between the upper surface of the Group III nitride semiconductor layer structure and the anti-nucleation mask. In some embodiments, the dielectric layer comprises a silicon nitride layer. In some embodiments, the silicon nitride layer includes an opening that overlaps the opening in the anti-nucleation mask, and wherein the Group III nitride semiconductor region extends into the opening in the silicon nitride layer.

In some embodiments, the semiconductor device comprises a Group III nitride RF transistor amplifier that includes a gate electrode, a drain electrode and a source electrode. In some embodiments, the Group III nitride semiconductor region directly contacts either the drain electrode or the source electrode. In some embodiments, the drain electrode is within the opening in the anti-nucleation mask. In some embodiments, the Group III nitride semiconductor region comprises at least part of the gate electrode.

Pursuant to other embodiments of the present invention, semiconductor devices are provided that comprise a Group III nitride semiconductor layer structure that has an upper surface that includes a recess; and a Group III nitride semiconductor region in the recess, the Group III nitride semiconductor region also protruding upwardly above the upper surface of the Group III nitride semiconductor layer structure. The Group III nitride semiconductor region includes a first portion having a first crystalline structure and a second portion that has a second crystalline structure that is different from the first crystalline structure.

In some embodiments, the second crystalline structure is a polycrystalline crystal structure and the first crystalline structure is a single crystalline crystal structure.

In some embodiments, the first crystalline structure is a polycrystalline crystal structure having a first average grain size and the second crystalline structure is a polycrystalline crystal structure having a second average grain size that is at least twice the first average grain size.

In some embodiments, the second portion surrounds the first portion in plan view.

In some embodiments, the second portion has an annular ring shape.

In some embodiments, the semiconductor device further comprises a dielectric layer on an upper surface of the Group III nitride semiconductor layer structure, the dielectric layer including an opening, wherein an upper portion of the Group III nitride semiconductor region is within the opening in the dielectric layer. In some embodiments, the dielectric layer comprises a silicon nitride layer.

Pursuant to yet additional embodiments of the present invention, semiconductor devices are provided that comprise a Group III nitride semiconductor layer structure; a dielectric layer on an upper surface of the Group III nitride semiconductor layer structure, the dielectric layer including an opening; and a first Group III nitride semiconductor region within the opening, where the first Group III nitride semiconductor region is a polycrystalline region having an annular shape.

In some embodiments, the semiconductor device further comprises a second Group III nitride semiconductor region, where the first Group III nitride semiconductor region surrounds the second Group III nitride semiconductor region when the semiconductor device is viewed from above.

In some embodiments, semiconductor crystals of the first Group III nitride semiconductor region have an average grain size that is at least twice an average grain size of semiconductor crystals of the second Group III nitride semiconductor region.

In some embodiments, the Group III nitride semiconductor layer structure includes a recess that is aligned with the opening in the dielectric layer.

In some embodiments, the second Group III nitride semiconductor region is within the recess.

### BRIEF DESCRIPTION OF THE FIGURES

FIGS. 1A-1E are schematic cross-sectional views that illustrate a method of selectively forming Group III nitride semiconductor regions in a Group III nitride semiconductor layer structure according to embodiments of the present invention.

FIG. 1F is an enlarged view of the portion of FIG. 1E in the box labelled 1F.

FIGS. 2A-2D are schematic cross-sectional views that illustrate another method of selectively forming Group III nitride semiconductor regions in a Group III nitride semiconductor layer structure according to embodiments of the present invention.

FIG. 3 is a flow chart of a method of forming a semiconductor device according to embodiments of the present invention.

FIG. 4A is simplified schematic plan view illustrating selected of the metal layers that are formed on an upper surface of a semiconductor layer structure of a conventional Group III nitride RF transistor amplifier die.

FIG. 4B is a schematic cross-sectional view taken along line 4B-4B of FIG. 4A.

FIG. 5 is a schematic cross-sectional view illustrating a Group III nitride regrowth process that is used to form ohmic contacts in a conventional Group III nitride RF transistor amplifier.

FIG. 6 is a schematic cross-sectional view of a unit cell of a Group III nitride RF transistor amplifier die according to certain embodiments of the present invention.

FIG. 7 is a schematic cross-sectional view of a unit cell of a Group III nitride RF transistor amplifier die according to further embodiments of the present invention.

FIG. 8 is a flow chart of a method of forming a Group III nitride RF transistor amplifier according to embodiments of the present invention.

FIG. 9 is a schematic cross-sectional view of a unit cell of a Group III nitride power switching device according to certain embodiments of the present invention.

FIG. 10 is a schematic cross-sectional view of a unit cell of a Group III nitride enhancement mode power switching device according to certain embodiments of the present invention.

FIG. 11 is a schematic cross-sectional view of a unit cell of a modified version of the Group III nitride RF transistor amplifier die of FIG. 6.

### DETAILED DESCRIPTION

As discussed above, there are various applications where it is desirable to have an MOCVD epitaxial grown Group III nitride semiconductor layer structure that has regions that are at the same depth that have different doping concentrations, doping types, molar compositions and/or constituent elements (also referred to herein as “different characteristics”) such as, for example, the formation of ohmic contact regions in Group III nitride RF transistor amplifier. These ohmic contact regions are typically formed either by ion implantation or by removing selected portions of the Group III nitride semiconductor layer structure to form recesses and selectively regrowing Group III nitride material having different characteristics in the recesses. In addition, there are other applications where it may be advantageous to selectively grow Group III nitride regions on an upper surface of a Group III nitride semiconductor layer structure such as, for example, growing a p-type GaN layer to support enhancement mode transistor operation or to shift a threshold voltage of a transistor to be more positive. Unfortunately, the current techniques used to form such ohmic contact regions and/or to perform a secondary Group III nitride growth process have certain disadvantages.

For example, if ohmic contacts are to be formed by ion implantation (as opposed to selective regrowth), a mask may be formed on the Group III nitride semiconductor layer structure and the regions of the Group III nitride semiconductor layer structure that require different doping concentrations/types may be exposed through openings in the mask and implanted with dopant ions via ion implantation. Ion implantation adds extra processing steps and the high energy implantation process may damage the semiconductor crystal structure, which may degrade the performance of the semiconductor device. In addition, the implanted dopant ions are typically activated using a very high temperature “activation anneal” which in some cases may be performed at temperatures that are higher than the growth temperatures. This activation anneal can cause a number of issues including potentially degrading the quality of the heterointerfaces.

Selective regrowth of Group III nitride material (whether or not the selectively grown Group III nitride is within a recess in the Group III nitride semiconductor layer structure) also has issues. Selective regrowth is typically performed by depositing a dielectric layer on the Group III nitride semiconductor layer structure and then etching the dielectric layer using a photoresist mask as an etch mask to provide a patterned dielectric layer that exposes selected regions of the upper surface of the Group III nitride semiconductor layer structure. The etching step may optionally etch recesses into the upper surface of the Group III nitride semiconductor layer structure. The photoresist mask is then removed. Then, an MBE (or other) growth process is performed to selectively grow Group III nitride regions on/in the exposed regions of the Group III nitride semiconductor layer structure. The regrown Group III nitride regions may have any desired constituent elements, doping types, molar compositions and doping concentrations. However, during the regrowth process, a polycrystalline Group III nitride layer nucleates and grows on the exposed surfaces of dielectric layer. Additional masking and wet etching steps are then required to remove this polycrystalline Group III nitride layer and the patterned dielectric layer. These additional processing steps increase manufacturing costs and cycle time, potentially reduce yield, and disadvantageously expose surface layers to additional etch chemistries during the removal of the patterned dielectric layer which can potentially negatively affect device performance.

Pursuant to embodiments of the present invention, methods of selective growth of Group III nitride regions are provided which use an anti-nucleation mask during the regrowth process that suppresses nucleation of any Group III nitride material on the anti-nucleation mask. Pursuant to these methods, a mask that is resistant to the nucleation of at least some Group III nitride semiconductor materials thereon, at least under appropriate growth conditions, is formed on (either directly or indirectly) a Group III nitride semiconductor layer structure. Herein, such a mask is referred to as an “anti-nucleation mask.” For example, the anti-nucleation mask may be a mask that is resistant to nucleation of at least GaN or InGaN during nitrogen plasma MBE growth processes. Such an anti-nucleation mask may be more specifically referred to herein as a “GaN/InGaN anti-nucleation mask.” The anti-nucleation mask may comprise, for example, an alumina (Al₂O₃) mask. An alumina mask may resist nucleation of GaN and InGaN during nitrogen plasma MBE growth processes, and may also resist nucleation of low aluminum content (which is defined herein as the Group III component is no more than 20% Al) AlGaN during the MBE growth process. Thus, an alumina mask may act as a GaN/InGaN/Low Al AlGaN anti-nucleation mask. The anti-nucleation mask may include openings therein that are above regions of the Group III nitride semiconductor layer structure that require different characteristics. A growth process such as, for example, an MBE growth process may be used to grow Group III nitride semiconductor materials in or on regions of the Group III nitride semiconductor layer structure that are exposed through the openings in the anti-nucleation mask. In some applications, recesses may be etched into the upper surface of Group III nitride semiconductor layer structure so that the regrown Group III nitride semiconductor materials are at least partially embedded in the Group III nitride semiconductor layer structure, but embodiments of the present invention are not limited thereto. Because the anti-nucleation mask inhibits the regrowth of Group III nitride thereon, no polycrystalline Group III nitride layer is formed on the anti-nucleation mask, and hence subsequent masking and etching steps for removing such a polycrystalline Group III nitride layer are not necessary. The anti-nucleation mask may then be removed after the selective regrowth process or, in many applications, may be left in place to serve as an insulating or passivation (or other functional) layer of the operational semiconductor device.

In some cases, one or more dielectric layers such as a silicon oxide layer or a silicon nitride layer may be formed in between the Group III nitride semiconductor layer structure and the anti-nucleation mask. The dielectric layer may include openings that are aligned with the respective openings in the anti-nucleation mask. Moreover, the silicon oxide or silicon nitride dielectric layer will typically support growth of polycrystalline Group III nitride material during the selective regrowth process. For example, a silicon nitride or silicon oxide layer may be interposed between the Group III nitride semiconductor layer and the anti-nucleation mask, and openings are provided in this dielectric layer underneath the respective openings in the anti-nucleation mask to expose selected regions of the Group III nitride semiconductor layer structure. The sidewalls of the openings in the dielectric layer are exposed during the Group III nitride regrowth process. Consequently, a polycrystalline Group III nitride layer may nucleate on the exposed portions of the silicon nitride or silicon oxide layer during the Group III nitride regrowth process, such as along sidewalls of the openings in the dielectric layer. While the presence of such polycrystalline Group III nitride layer is generally not desirable, as the polycrystalline Group III nitride will generally have less desirable electrical and other properties as compared to the regrown Group III nitride regions (which are often single crystalline regions), the polycrystalline Group III nitride layer typically will not materially impact the properties of many devices.

In some embodiments of the present invention, the above-described selective Group III nitride regrowth techniques using anti-nucleation masks may be used to form the ohmic contact regions that underlie the metal source and drain electrodes of a Group III nitride RF transistor amplifier or other Group III nitride transistor. The ohmic contact regions are typically very heavily doped regions, yet are at the same depth in the RF transistor amplifier as other regions such as channel, barrier and/or capping layers that are much more lightly doped or even undoped regions. The Group III nitride semiconductor layer structure for such RF transistor amplifiers may be doped during epitaxial growth to have the appropriate doping concentrations, molar compositions and constituent elements for the channel layer, the barrier layer, and any capping layer. The regions in the semiconductor layer structure where the ohmic contact regions are to be formed may, for example, then be selectively removed to provide recesses in the Group III nitride semiconductor layer structure (although in some cases the recesses may be omitted). An anti-nucleation mask is formed that covers the Group III nitride semiconductor layer structure and that has openings that expose the recessed regions therein. Much more heavily doped ohmic contact regions may then be formed in the recesses using a selective Group III nitride regrowth step, and growth of Group III nitride material is inhibited in other regions of the device by the anti-nucleation mask. Moreover, in some embodiments, the anti-nucleation mask may be left in place (eliminating the need for any mask stripping process) to serve as an insulating layer that is interposed between the gate electrode and a field plate and/or to serve as a passivation layer.

In other embodiments, the above techniques may be used to form a plurality of p-type Group III nitride gate electrodes (e.g., p-type GaN gate electrodes) of a Group III nitride RF transistor amplifier or of a MISHEMT power switching device. The Group III nitride semiconductor device may include a Group III nitride semiconductor layer structure. The p-type Group III nitride gate electrodes may be formed on a Group III nitride semiconductor layer structure, and may extend into recesses in an upper surface of the Group III nitride semiconductor layer structure in some embodiments. The p-type Group III nitride gate electrodes may or may not be separated from the Group III nitride semiconductor layer structure by a thin dielectric layer. An anti-nucleation mask may cover the Group III nitride semiconductor layer structure and may have openings that expose the regions where the p-type gate electrodes are to be formed. The p-type Group III nitride gate electrodes may be formed in those regions without Group III nitride material nucleating on the anti-nucleation mask.

In any of the above embodiments, the anti-nucleation mask may be a GaN/InGaN anti-nucleation mask or a GaN/InGaN/Low Al AlGaN anti-nucleation mask such as an alumina mask.

Embodiments of the present invention will now be discussed in greater detail with reference to the attached figures.

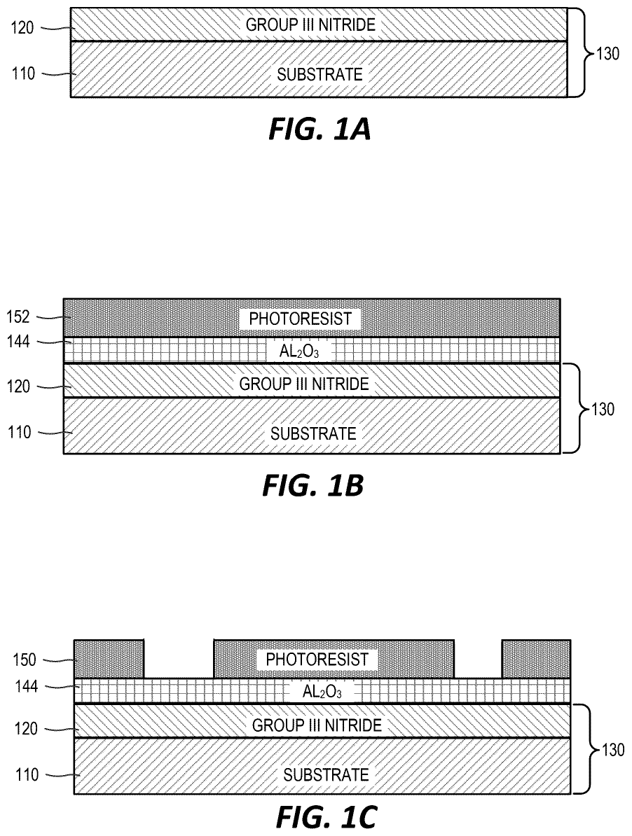

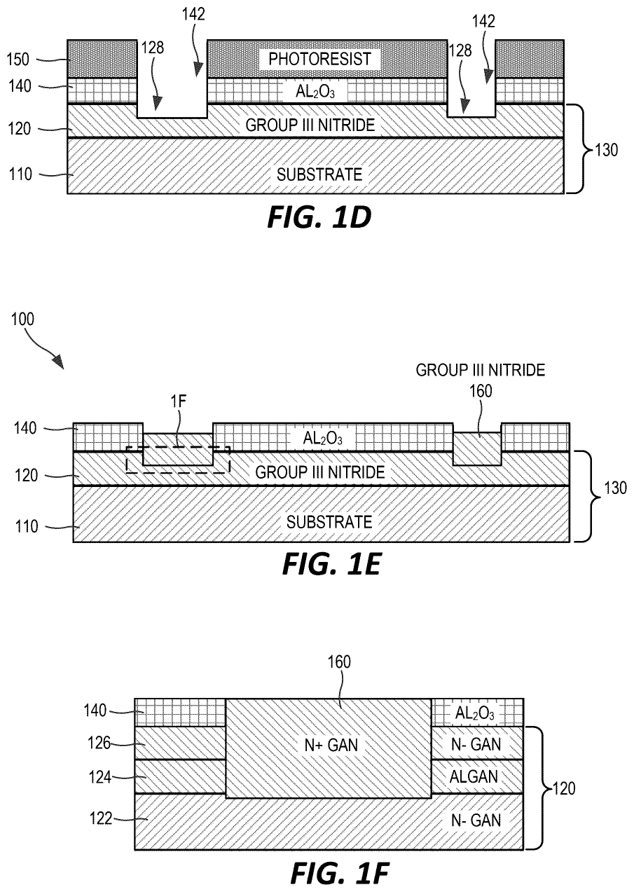

Pursuant to some embodiments of the present invention, methods of selectively forming Group III nitride semiconductor regions in and/or on a Group III nitride semiconductor layer structure are provided. FIGS. 1A-1E are schematic cross-sectional views that illustrate one such method according to embodiments of the present invention.

Referring to FIG. 1A, one or more Group III nitride epitaxial layers 120 (element 120 may represent a single layer or multiple layers) are epitaxially grown on a growth substrate 110 to provide a Group III nitride semiconductor layer structure 130. The growth substrate 110 may comprise, for example, a semi-insulating silicon carbide substrate, a sapphire substrate, a silicon substrate, a Group III nitride substrate, or any other substrate on which the Group III nitride epitaxial layers 120 may be formed. The Group III nitride epitaxial layers 120 may comprise at least one Group III nitride layer. The Group III nitride epitaxial layers 120 may be formed on the growth substrate 110 using, for example, an MOCVD growth process.

Referring FIG. 1B, an anti-nucleation mask layer 144 is formed on the Group III nitride semiconductor layer structure 130. The anti-nucleation mask layer 144 may comprise, for example, an alumina (Al₃O₂) mask layer. The anti-nucleation mask layer 144 may be formed using ALD in some embodiments. In some embodiments, the anti-nucleation mask layer 144 may comprise a material on which Group III nitride materials (e.g., amorphous or polycrystalline Group III nitride materials) do not readily grow during a particular MBE Group III nitride semiconductor growth process (i.e., Group III nitride materials will not nucleate on the anti-nucleation mask layer material during a selective Group III nitride regrowth process). Next, a photoresist layer 152 is formed on the anti-nucleation mask layer 144.

Referring to FIG. 1C, the photoresist layer 152 is patterned using photolithography techniques to form a photoresist pattern 150.

Referring to FIG. 1D, an etching process is then performed using the etch mask 150 as an etching mask to pattern the anti-nucleation mask layer 144 to convert it into an anti-nucleation mask 140 that has one or more openings 142 therein. The openings 142 in the anti-nucleation mask 140 expose the upper surface of the one or more Group III nitride epitaxial layers 120. As is further shown in FIG. 1D, the etching process (which may be a multi-part etching process) may (optionally) also etch away the upper portions of the Group III nitride semiconductor layer structure 130 that are exposed by the openings 142 in the anti-nucleation mask 140, thereby forming a plurality of recesses 128 in the upper surface of the one or more Group III nitride epitaxial layers 120.

Referring to FIG. 1E, the photoresist etch mask 150 is removed. An MBE growth process is then performed to selectively grow Group III nitride semiconductor material 160 in the recesses 128 (or on the upper surface of the Group III nitride semiconductor layer structure 130 if the recesses 128 are not provided). The MBE growth process may use a nitrogen plasma, which may help suppress nucleation of Group III nitride material on the anti-nucleation mask 140. The selectively grown Group III nitride semiconductor material 160 grows upwardly from the Group III nitride semiconductor layer structure 130, which acts as a seed for growth, and may partially fill the recesses 128, completely fill the recesses 128, or completely fill the recesses 128 and then extend out of the recesses 128 into the openings 142 in the anti-nucleation mask 140 (as shown). No Group III nitride semiconductor material 160 grows on the upper surface of the anti-nucleation mask 140 since the anti-nucleation mask 140 does not support Group III nitride material nucleation. After the selectively grown Group III nitride semiconductor material 160 is formed in the recesses 128, the anti-nucleation mask 140 may be removed or may be left in place where it may, for example, serve as an insulating layer or passivation layer of a semiconductor device 100.

The Group III nitride semiconductor material 160 that is formed in the recesses 128 may have different characteristics than the Group III nitride epitaxial layers 120. For example, the doping type, doping concentration, degree of crystallinity, constituent elements and/or relative mole concentrations of a first portion of the Group III nitride semiconductor material 160 may differ from the doping type, doping concentration, degree of crystallinity and/or constituent elements or relative mole concentrations of a second portion of the Group III nitride epitaxial layers 120 that is at a same height above a plane defined by a lower surface of the Group III nitride epitaxial layers 120 as the first portion of the Group III nitride semiconductor material 160 and that contacts the Group III nitride semiconductor material 160. This is schematically shown in FIG. 1F, which is an enlarged view of the portion of the semiconductor device 100 of FIG. 1E that is within the dashed box labelled 1F. As shown in FIG. 1F, the Group III nitride semiconductor material 160 may comprise a heavily doped GaN region and the Group III nitride epitaxial layers 120 may comprise a lightly doped or undoped first GaN layer 122, a lightly doped or undoped AlGaN layer 124 on the first GaN layer122, and an optional GaN or AlGaN capping layer 126 on the AlGaN layer 124.

As can be seen in FIG. 1F, since the Group III nitride semiconductor material 160 is regrown in a separate step from the epitaxial growth step used to form layers 122, 124, 126, the Group III nitride semiconductor material 160 may have a first doping concentration (highly doped) and be formed of a first combination of constituent elements (GaN here, but InGaN or other alloys in other embodiments) while horizontally overlapping other layers 122, 124, 126 that have different doping concentrations (light or undoped) and/or a different combination of constituent elements (AlGaN here, but other alloys are possible). Herein, two elements or layers of a semiconductor device are considered to “horizontally overlap” if an axis that is parallel to a major surface of the semiconductor layer structure of the device extends through both elements or layers. It will be appreciated that the Group III nitride semiconductor material 160 may have a generally constant doping concentration or a graded doping concentration and/or may have a fixed alloy composition (e.g., GaN throughout) or may have a graded alloy composition (e.g., graded from GaN to InGaN).

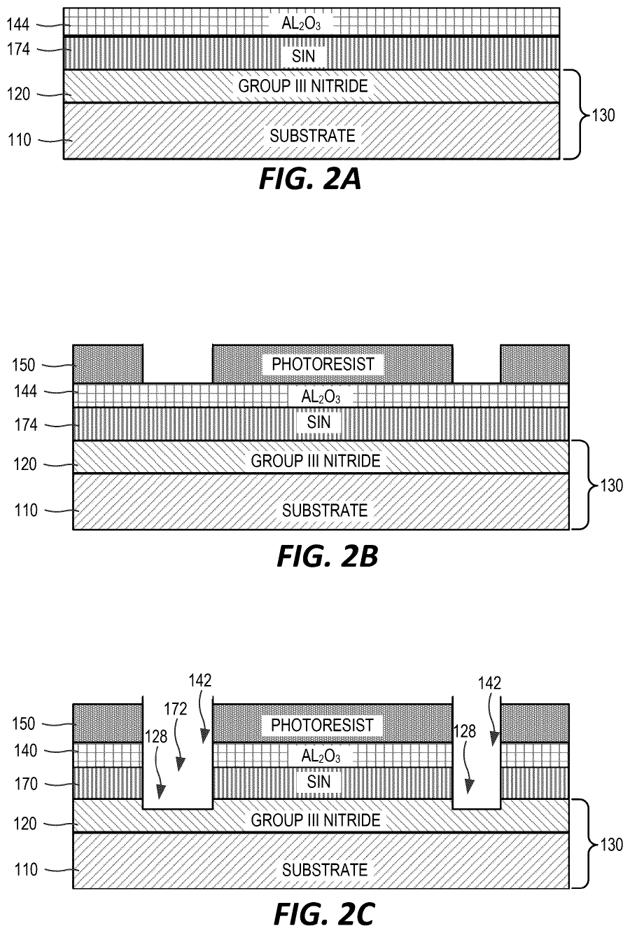

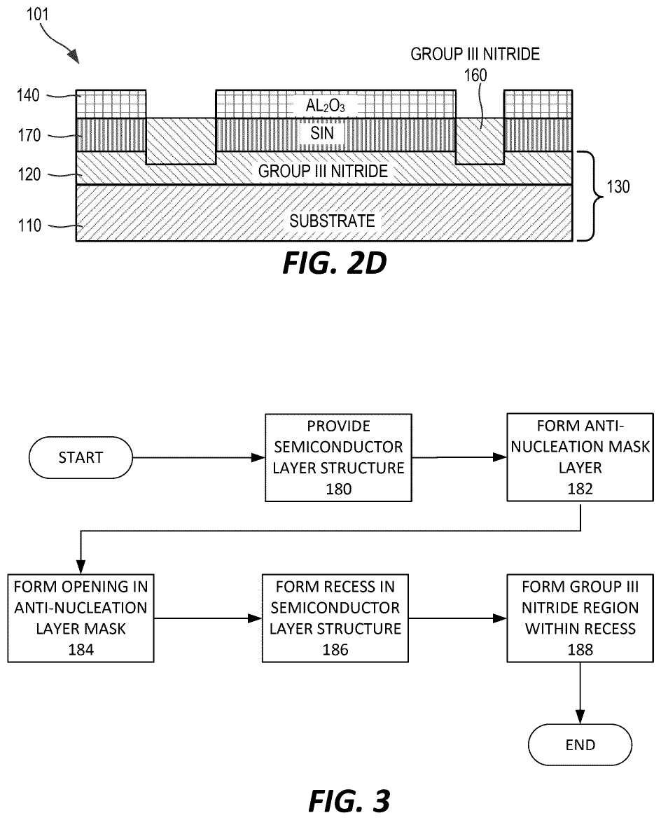

FIGS. 2A-2D are schematic cross-sectional views that illustrate another method according to embodiments of the present invention of selectively forming Group III nitride semiconductor regions having different properties.

Referring to FIG. 2A, one or more Group III nitride epitaxial layers 120 are epitaxially grown on a growth substrate 110 to form a Group III nitride semiconductor layer structure 130 in the same manner discussed above with reference to FIG. 1A. Next, one or more additional layers 174 that are not Group III nitride layers is/are formed on the upper surface of the one or more Group III nitride epitaxial layers 120. For example, a dielectric layer 174 such as a silicon nitride (SiN) layer may be formed on the Group III nitride epitaxial layers 120. In the depicted embodiment, the one or more additional layers 174 is a single silicon nitride (“SiN”) layer, but it will be appreciated that the one or more additional layers 174 may comprise any of a wide variety of insulating layers, semiconductor layers, metal layers and the like. Next, an anti-nucleation mask layer 144 is formed on the one or more layers 174. The anti-nucleation mask layer 144 may be identical to the anti-nucleation mask layer 144 discussed above with reference to FIG. 1B.

Referring FIG. 2B, a photoresist layer is formed on the anti-nucleation mask layer 144 and is then patterned using photolithography techniques to provide an etch mask 150. The etch mask 150 may be formed in the same manner discussed above with reference to FIGS. 1B and 1C.

Referring FIG. 2C, an etching process is then performed using the etch mask 150 as an etching mask to convert the anti-nucleation mask layer 144 into an anti-nucleation mask 140 that has one or more openings 142 therein, and to convert the one or more additional layers 174 (which here are shown as a single silicon nitride layer) into an additional layer pattern 170 that has one or more openings 172 therein. The openings 142 in the anti-nucleation mask 140 and the openings 172 in the silicon nitride layer 170 expose selected portions of the upper surface of the one or more Group III nitride layers 120. As is further shown in FIG. 2C, the second etching process may also (optionally) etch away the upper portions of the semiconductor layer structure 130 that are exposed by the openings 142 in the anti-nucleation mask 140 and the openings 172 in the additional layer pattern 170, thereby forming a plurality of recesses 128 in the upper portion of the one or more Group III nitride layers 120.

Referring to FIG. 2D, next an MBE (or other) growth process is performed. This results in selective growth of Group III nitride semiconductor material 160 in the recesses 128. The selectively grown Group III nitride semiconductor material 160 may partially fill the recesses 128, completely fill the recesses 128, or completely fill the recesses 128 and then extend out of the recesses 128. The Group III nitride semiconductor material 160 does not grow on the anti-nucleation mask 140 since the anti-nucleation mask 140 does not support Group III nitride material nucleation (but may grow from the Group III nitride semiconductor layer structure 130 into the openings 142 so as to contact the anti-nucleation mask 140). After the selectively grown Group III nitride semiconductor material 160 is formed in the recesses 128, the anti-nucleation mask 140 may be removed or may be left in place where it may, for example, serve as an insulating or passivation layer of a semiconductor device 101.

Thus, as shown in FIGS. 1A-1F and 2A-2D, according to some embodiments of the present invention, semiconductor devices 100, 101 are provided that comprise a Group III nitride semiconductor layer structure 130 that may have a recess 128 in an upper surface thereof. An anti-nucleation mask 140 (e.g., an alumina mask) is provided on an upper surface of the Group III nitride semiconductor layer structure 130. The anti-nucleation mask 140 has an opening 142 that exposes the Group III nitride semiconductor layer structure 130. In addition, a selectively formed Group III nitride semiconductor region 160 is formed on the Group III nitride semiconductor layer structure 130 and in the recess 128 (if provided). In some embodiments, an upper portion of the Group III nitride semiconductor region 160 may be above a plane defined by the upper surface of the Group III nitride semiconductor layer structure 130.

A portion of the Group III nitride semiconductor region 160 and a portion of the Group III nitride semiconductor layer structure 130 that is at a same height above a plane defined by a lower surface of the Group III nitride semiconductor layer structure 130 may be different constituent elements. For example, the Group III nitride semiconductor region 160 may be GaN or InGaN and the Group III nitride semiconductor layer structure 130 may be AlGaN. The Group III nitride semiconductor region 160 and/or the Group III nitride semiconductor layer structure 130 may include graded portions in some embodiments.

As shown in FIGS. 2A-2D, the semiconductor device may further comprise a dielectric layer 170 that is between the upper surface of the Group III nitride semiconductor layer structure 130 and the anti-nucleation mask 140. The dielectric layer 170 may comprise, for example, a silicon nitride layer. The dielectric layer 170 may include an opening 172 that vertically overlaps the opening 142 in the anti-nucleation mask 140, and the Group III nitride semiconductor region 160 may extend into the opening 172 in the dielectric layer 170. Herein, two elements or layers of a semiconductor device are considered to “vertically overlap” if an axis that is perpendicular to a major surface of the semiconductor layer structure of the device extends through both elements or layers.

FIG. 3 is a flow chart illustrating a method of fabricating a Group III nitride semiconductor device according to some embodiments of the present invention. As shown in FIG. 3, a Group III nitride semiconductor layer structure such as Group III nitride semiconductor layer structure 130 may be provided (Block 180). An anti-nucleation mask layer such as anti-nucleation mask layer 144 is formed (directly or indirectly) on the Group III nitride semiconductor layer structure (Block 182), and the anti-nucleation mask layer 144 may be patterned to form an anti-nucleation mask 140 that includes one or more openings therein (Block 184). Alternatively, the anti-nucleation mask 140 having openings therein may be selectively formed on the Group III nitride semiconductor layer structure. The anti-nucleation mask 140 may be an alumina mask in some embodiments.

An optional etching step may be performed to form one or more recesses such as recesses 128 in an upper surface of the Group III nitride semiconductor layer structure (Block 186). The same etching step that is used to pattern the anti-nucleation mask layer 144 may be used to form the recesses 128. A Group III nitride regrowth operation may then be performed to form a Group III nitride semiconductor region such as Group III nitride region 160 on the Group III nitride semiconductor layer structure 130 and/or in the recess 128 (Block 188). In example embodiments, the Group III nitride semiconductor region may be formed by MBE. The Group III nitride semiconductor region 160 is formed in a manner such that Group III nitride semiconductor material does not nucleate on an exposed upper surface of the anti-nucleation mask 140.

It will be appreciated that some of the operations shown in FIG. 3 may be omitted such as, for example, operation 186. It will likewise be appreciated that some of the operations shown in FIG. 3 may be formed in a different order and/or that two or more of the operations may be performed simultaneously. Thus, it will be appreciated that the flow chart of FIG. 3 merely shows one example embodiment of the present invention.

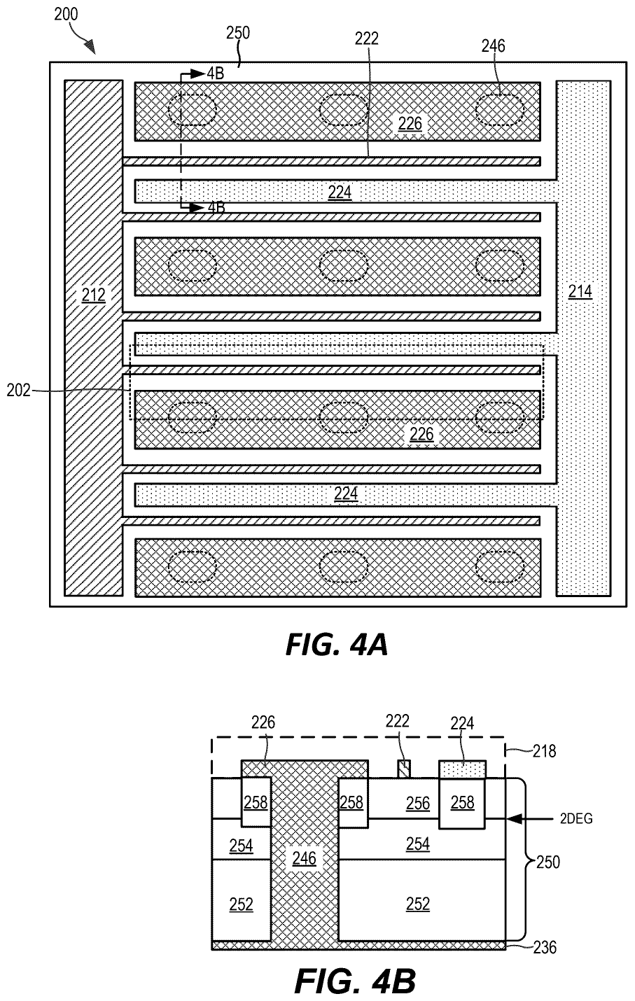

One application where the techniques disclosed herein may be used is in the fabrication of Group III nitride RF transistor amplifiers. As will be discussed in greater detail below, Group III nitride RF transistor amplifiers are typically implemented as high electron mobility transistors (“HEMTs”). In order to support high power operation, these Group III nitride RF transistor amplifiers have a unit cell structure where a large number of identical small transistor cells are electrically connected in parallel to each other. FIG. 4A is a schematic plan view of a conventional Group III nitride RF transistor amplifier die 200 that illustrates the metal layers that are formed directly on the upper surface of the Group III nitride semiconductor layer structure of the RF transistor amplifier die.

As shown in FIG. 4A, the RF transistor amplifier die 200 includes a gate bus 212 and a drain bus 214, a plurality of gate electrodes 222, a plurality of drain electrodes 224 and a plurality of source electrodes 226 that are formed on a Group III nitride semiconductor layer structure 250. The gate electrodes 222, drain electrodes 224 and source electrodes 226 may extend in parallel to each other, with the gate electrodes 222 extending from the gate bus 212 in a first direction and the drain electrodes 224 extending from the drain bus 214 in a direction opposite the first direction. Each gate electrodes 222 may be positioned between a drain electrodes 214 and a source electrodes 226.

The gate bus 212 and the gate electrodes 222 may be implemented as a first monolithic metal pattern. The gate electrodes 222 may be formed of materials that are capable of making a Schottky contact to a Group III nitride semiconductor material, such as Ni, Pt, Cu, Pd, Cr, W and/or WSiN. The gate bus 212 and the gate electrodes 222 are part of a gate electrode structure of the RF transistor amplifier die 200.

The drain bus 214 and the drain electrodes 224 may be implemented as a second monolithic metal pattern. The drain electrodes 224 may include a metal that can form an ohmic contact to Group III nitride materials. The drain bus 214 and the drain electrodes 224 are part of a drain electrode of the RF transistor amplifier die 200.

The source electrodes 226 may include a metal that can form an ohmic contact to Group III nitride materials. The source electrodes 226 are physically and electrically connected to a source terminal 236 (see FIG. 4B) of the RF transistor amplifier die 200 that is located on the bottom side of the Group III nitride semiconductor layer structure 250 by a plurality of metal-plated source vias 246. Each metal-plated source via 246 may extend from a source electrode 226 through the Group III nitride semiconductor layer structure 250. Each metal-plated source via 246 may each be implemented by forming openings though the semiconductor layer structure 250 (e.g., by anisotropic etching) and by then depositing metal-plating that coats the sidewalls of the openings (and that optionally may fill the openings).

One or more interlayer insulating layers 218 (see FIG. 4B) are formed that isolate the gate metallization 212, 222, the drain metallization 214, 224 and the source metallization 226 from each other. The interlayer insulating layer(s) 218 may include a dielectric material, such as SiN, SiO₂, etc. The interlayer insulating layers 218 are shown in FIG. 4B using a dashed box as these layers are omitted in FIG. 4A.

The RF transistor amplifier die 200 includes a plurality of unit cell transistors 202, one of which is indicated in the dashed box in FIG. 4A. The unit cell transistor 202 includes a gate electrode 222, a portion of a drain electrode 224 and a portion of a source electrode 226 along with the portions of the Group III nitride semiconductor layer structure 250 underlying the identified gate electrode 222, drain electrode 224 and source electrode 226. Since all of the gate electrodes 222 are electrically connected to a common gate bus 212, all of the drain electrodes 224 are electrically connected to a common drain bus 214, and all of the source electrodes 226 are electrically connected to a common source terminal 236, it can be seen that the unit cell transistors 202 are all electrically connected together in parallel.

FIG. 4B is a schematic cross-sectional view taken along line 4B-4B of FIG. 4A. As shown in FIG. 4B, the Group III nitride semiconductor layer structure 250 includes a plurality of semiconductor layers. In the depicted embodiment, a total of two semiconductor layers are shown, namely a channel layer 254 and a barrier layer 256 that is on an upper surface of the channel layer 254. The Group III nitride semiconductor layer structure 250 may (and typically will) include additional semiconductor and/or non-semiconductor layers. For example, the Group III nitride semiconductor layer structure 250 may include a growth substrate 252 (e.g., a SiC, silicon or Group III nitride growth substrate) on which the other semiconductor layers are grown. The growth substrate 252, even if formed of a non-semiconductor material, is considered to be part of the Group III nitride semiconductor layer structure 250. Optional buffer, nucleation and/or transition layers (not shown) may be provided on the growth substrate 252 beneath the channel layer 254 such as, for example, an AlN buffer layer or one or more strain balancing transition layer(s).

The channel layer 254 is a Group III nitride material, such as AlₓGa₁₋ₓN where 0≤x<1. Most typically, the channel layer 254 is gallium nitride (“GaN”). The channel layer 254 may be undoped or unintentionally doped. The channel layer 254 may also be a multi-layer structure, such as a superlattice or combinations of InGaN, GaN, AlGaN or the like. The barrier layer 256 may be a Group III nitride such as, for example, an AlN, AlInN, AlGaN, AlInGaN, ScGaN, ScAlGaN, ScAlN, ScInAl,GaN layer or combinations of layers thereof. The barrier layer 256 may be undoped or doped with an n-type dopant to a concentration less than about 1×10¹⁸/cm³.

Ohmic contact regions 258 may optionally be formed in the barrier layer 256 and/or in layers of the semiconductor layer structure (not shown) that are on top of the barrier layer 256 underneath the drain electrodes 224 and the source electrodes 226. The ohmic contact regions 258 may also optionally extend into an upper portion of the channel region 254, as shown. The ohmic contact regions 258 may comprise regions that are configured to make good ohmic contacts to the metal drain and source electrodes 224, 226.

The channel layer 254 may have a bandgap that is less than the bandgap of at least a portion of the barrier layer 256, and the channel layer 254 may also have a larger electron affinity than the barrier layer 256. The energy of the conduction band edge of the channel layer 254 is less than the energy of the conduction band edge of the barrier layer 256 at the interface between the channel and barrier layers 254, 256. The barrier layer 256 may be thick enough and have a high enough Al composition and doping to induce a significant carrier concentration at the interface between the channel layer 254 and the barrier layer 256.

As known in the art, when the gate, drain and source electrodes 222, 224, 226 are connected to suitable direct current bias voltages (which may be the absence of any applied voltages, as “normally-on” HEMTs are designed to be in their conducting on-state in the absence of any applied gate voltage and are turned off by applying a sufficiently high negative gate voltage) and an RF signal is applied to the gate electrode 222, the difference in bandgap between the barrier layer 256 and the channel layer 254 and piezoelectric effects at the interface between the barrier layer 256 and the channel layer 254 act to induce a two dimensional electron gas (2DEG) in the channel layer 254 at the junction between the channel layer 254 and the barrier layer 256. The 2DEG acts as a highly conductive channel that allows conduction between the ohmic contact region 258 underneath the source electrode 226 and the ohmic contact region 258 underneath the drain electrode 224 of each unit cell 202.

Since the layers of the Group III nitride semiconductor layer structure 250 are formed via epitaxial growth, each layer will have the same constituent elements, molar compositions, doping type and doping concentration throughout the respective layer (at least at any given depth). Thus, while the constituent elements, molar compositions, doping type and doping concentration may be varied during the growth process as a function of the depth of the Group III nitride semiconductor layer structure 250, regions cannot be formed during the growth process that have different constituent elements, molar compositions, doping type and/or doping concentrations at the same depth in the Group III nitride semiconductor layer structure 250 without performing specialized (and more complex) growth techniques. As such, it typically is not commercially practicable to form the above-discussed ohmic contact regions 258 during the epitaxial growth process to have different characteristics than the barrier layer 256 and/or any capping layers (not shown) on the barrier layer 256.

The constituent elements (e.g., Ga, Al, N, etc.) forming the semiconductor layers in the upper portion of the semiconductor layer structure 250 (e.g., the barrier layer 256 and any capping layers (not shown) on the barrier layer 256) and any doping thereof typically are primarily selected to facilitate formation of a strong 2DEG layer during device operation. For example, to form the 2DEG region, the barrier layer 256 must have a higher bandgap than the channel layer 254. Thus, the barrier layer 256 is typically implemented as an AlGaN layer while the channel layer 254 is typically implemented as a GaN layer to provide the necessary bandgap differential. The barrier layer 256 is typically only unintentionally doped with dopants (e.g., a dopant concentration of between 1×10¹⁵−1×10¹⁶/cm³).

Unfortunately, the semiconductor materials and doping profiles that facilitate formation of a strong 2DEG layer during device operation typically do not provide the best ohmic contacts to the metal drain and source electrodes 224, 226. Thus, the ohmic contact regions 258 may be provided so that the quality of the ohmic contacts between the metal drain and source electrodes 224, 226 and the Group III nitride semiconductor layer structure 250 is improved. Moreover, for Group III nitride RF transistor amplifiers that operate at very high (e.g., millimeter wave) frequencies, the size of the device is scaled down and the doping concentration of the barrier layer 256 is increased to maintain sufficiently large carrier concentrations in the barrier layer for good 2DEG performance. With such high aluminum content barrier layers it may become difficult or even impossible to make a good ohmic contact.

In some conventional devices, after the Group III nitride semiconductor layer structure 250 is formed, an ion implantation step is performed to selectively form heavily doped ohmic contact regions 258 in the Group III nitride semiconductor layer structure 250 underneath the metal drain and source electrodes 224, 226. The high doping levels decrease the resistance of the ohmic contact regions 258 providing for improved ohmic contacts. The ion implantation process requires an extra mask formation process, the ion implantation process, and a mask removal process, which increases fabrication costs. In addition, the ion implantation process may damage the semiconductor crystal in the ohmic contact regions 258, the high temperature annealing step that is used to activate the implanted dopant ions may result in heterostructure interface smearing, which may lower carrier mobility, and/or surface damage may occur if the implant mask reacts with the barrier later resulting in dispersion or surface leakage.

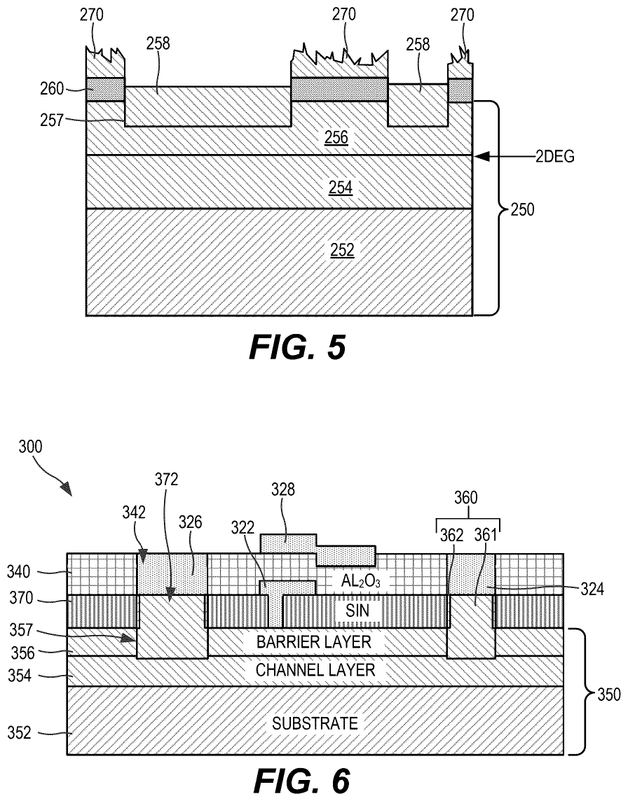

In other cases, the upper portions of the Group III nitride semiconductor layer structure 250 that underlie the drain and source electrodes 224, 226 may be removed after the Group III nitride semiconductor layer structure 250 is formed to form longitudinally-extending recesses therein. FIG. 5 is a cross-sectional view of a unit cell of a conventional RF transistor amplifier that illustrates the regrowth process. As shown in FIG. 5, a silicon oxide layer is formed on the semiconductor layer structure 250 and then patterned to form a silicon oxide mask 260. An etching process is performed to form the recesses 257 in the Group III nitride semiconductor layer structure 250. Group III nitride semiconductor regions 258 are then regrown (or otherwise formed) within the recesses 257 to form the ohmic contact regions 258 in the Group III nitride semiconductor layer structure 250, using the exposed Group III nitride material in the bottom of the recesses 257 as a seed to regrow the Group III nitride material that forms the ohmic contact regions 258. Unfortunately, during this growth process, a polycrystalline GaN layer 270 typically forms on the silicon oxide mask 260, as is schematically shown in FIG. 5. The polycrystalline GaN layer 270 must thereafter be removed using a wet etching technique with appropriate masking which can significantly increase manufacturing costs and which may potentially damage the surface of the Group III nitride semiconductor layer structure, resulting in dispersion.

As discussed above, pursuant to some embodiments of the present invention, methods of forming Group III nitride RF transistor amplifiers are provided in which Group III nitride ohmic contact regions are regrown within recesses in a Group III nitride semiconductor layer structure using an anti-nucleation mask during the regrowth process so that the above-discussed polycrystalline GaN layer 270 does not form during the regrowth process.

FIG. 6 is a schematic perspective cross-sectional view of a unit cell 300 of a Group III nitride RF transistor amplifier die according to certain embodiments of the present invention that is formed in this manner.

As shown in FIG. 6, the unit cell 300 includes a Group III nitride semiconductor layer structure 350. The Group III nitride semiconductor layer structure 350 comprises a substrate 352, a Group III nitride channel layer 354 on the substrate 352, and a Group III nitride barrier layer 356 on the channel layer 354 opposite the substrate 352. The substrate 352, the Group III nitride channel layer 354, and the Group III nitride barrier layer 356 may be identical to the corresponding elements of RF transistor amplifier die 200, so further description thereof will be omitted here. It will be appreciated that additional layers may be included in the Group III nitride semiconductor layer structure 350, and/or that the growth substrate 352 may optionally be omitted (e.g., removed after growth). As is further shown in FIG. 6, recesses 357 are formed (e.g., by etching) in the upper surface of the Group III nitride semiconductor layer structure 350.

As shown in FIG. 6, a dielectric layer 370 is formed on an upper surface of the Group III nitride semiconductor layer structure 350. The dielectric layer 370 may comprise a silicon nitride layer in some embodiments, as silicon nitride may act as a passivation layer and may also help eliminate trapped charge centers in the upper surface of the Group III nitride semiconductor layer structure 350. Openings 372 are formed in the dielectric layer 370.

An anti-nucleation mask 340 is formed on the dielectric layer 370 opposite the Group III nitride semiconductor layer structure 350. The anti-nucleation mask 340 has openings 342 formed therein that may be above and aligned with the openings 372 in the dielectric layer 370. The anti-nucleation mask 340 may comprise an alumina mask in example embodiments.

After the anti-nucleation mask 340 is formed, an MBE growth process is performed to regrow Group III nitride semiconductor region 360 in the recesses 357. In example embodiments, the MBE process may be performed using a nitrogen plasma. The Group III nitride semiconductor material does not nucleate on the anti-nucleation mask 340, and hence the Group III nitride semiconductor material may only form in the recesses 357 and then grow upwardly.

The Group III nitride semiconductor region 360 that is formed in the recesses 357 by a secondary growth process (here an MBE growth process) may comprise a heavily-doped n-type GaN region in some embodiments. The Group III nitride semiconductor material in each Group III nitride semiconductor region 360 may have a doping concentration between 1×10¹⁹ and 1×10²¹ dopants/cm³ in example embodiments. Forming the Group III nitride semiconductor material in the Group III nitride semiconductor region 360 as GaN may allow for higher doping concentrations, and hence an improved ohmic contact, as compared to regions formed using AlGaN. It should be noted that the unit cell 300 has the same Group III nitride semiconductor layer structure as the Group III nitride semiconductor layer structure of the semiconductor device 101 of FIGS. 2A-2D, and has the same two insulating layers (namely a dielectric layer with an anti-nucleation mask thereon) formed on the upper surface of the semiconductor layer structure. Thus, it will be appreciated that the fabrication steps discussed above with respect to FIGS. 2A-2D may be used to fabricate the unit cell 300 of FIG. 6.

Still referring to FIG. 6, metal electrodes and other structures are formed on the upper surface of the Group III nitride semiconductor layer structure 350. The metal structures include a gate electrode 322, a drain electrode 324, a source electrode 326 and a field plate 328.

Since Group III nitride materials do not nucleate on the anti-nucleation mask 340 during the growth of the Group III nitride semiconductor material in the Group III nitride semiconductor regions 360, there is no need for a wet etching step to remove polycrystalline Group III nitride material from the mask used in the Group III nitride regrowth process. This reduces manufacturing costs and avoids the potential for chemical damage or etching of the regrown region that can occur during the removal of the polycrystalline material. In addition, in some embodiments, the anti-nucleation mask 340 may be left in place to serve a functional purpose in the completed semiconductor device. For example, as shown in FIG. 6, the anti-nucleation mask 340 may be used as a dielectric layer that is interposed between the source-connected field plate 328 and the gate electrode 322. In other embodiments (e.g., embodiments that do not include a field plate 328), the anti-nucleation mask 340 may act as a passivation layer. In still other embodiments, a gate electrode that is connected to the field plate through an opening in the anti-nucleation mask may be formed in a single metal deposition step. Using the anti-nucleation mask 340 as a functional layer further removes any need to remove the anti-nucleation mask 340 after the regrowth process is completed.

Thus, as shown in FIG. 6, pursuant to some embodiments of the present invention, an RF transistor amplifier 300 is provided that comprises a Group III nitride semiconductor layer structure 350 that includes a channel layer 354 and a barrier layer 356. The barrier layer 356 has a higher bandgap than the channel layer 354 and is formed on an upper surface of the channel layer 354. The RF transistor amplifier further includes an anti-nucleation mask 340 on an upper surface of the Group III nitride semiconductor layer structure 350. In example embodiments, the anti-nucleation mask 340 may be an alumina mask. The anti-nucleation mask 340 has an opening 342 that exposes an exposed portion of the Group III nitride semiconductor layer structure 350. Additionally, a Group III nitride semiconductor region 360 may be provided in a recess 357 in the upper surface of the Group III nitride semiconductor layer structure 350.

In some embodiments, a portion of the Group III nitride semiconductor region 360 and a portion of the Group III nitride semiconductor layer structure 350 that is at a same height above a plane defined by a lower surface of the Group III nitride semiconductor layer structure 350 have different constituent element compositions, different doping concentrations, and/or different doping types.

The Group III nitride semiconductor region 360 may extend out of the recess 357 so that an upper portion of the Group III nitride semiconductor region 360 is above a plane defined by the upper surface of the Group III nitride semiconductor layer structure 350.

In some embodiments, the RF transistor amplifier 300 further comprises a silicon nitride layer 370 that is between the upper surface of the Group III nitride semiconductor layer structure 350 and the anti-nucleation mask 340.

The Group III nitride RF transistor amplifier 300 further includes a gate electrode 322, a drain electrode 324 and a source electrode 326. In some embodiments, the Group III nitride semiconductor region 360 may directly contact either the drain electrode 324 or the source electrode 326. In other embodiments, the Group III nitride semiconductor region 360 may form at least part of the gate electrode 322. In some embodiments, the Group III nitride RF transistor amplifier 300 may further include a field plate 328, and the anti-nucleation mask 340 may electrically insulate the field plate 328 from the gate electrode 322. In other cases, the field plate 328 may be connected to the gate electrode 322 through an opening in the anti-nucleation mask 340, and can be deposited in a single step by patterning the anti-nucleation mask 340 properly.

In the embodiment shown in FIG. 6, the openings 372 in the dielectric layer 370 are the same size as the openings 342 in the anti-nucleation mask 340. Thus, the upper surface of the silicon nitride layer 370 is not exposed during the secondary growth process. However, the sidewalls of each opening 372 are silicon nitride sidewalls. Consequently, during the Group III nitride regrowth operation that forms the Group III nitride semiconductor regions 360, polycrystalline Group III nitride material 362 (e.g., polycrystalline GaN) may form on the exposed silicon nitride in each opening 372 during the Group III nitride regrowth operation. The Group III nitride material may tend to nucleate more efficiently on the exposed portion of the Group III nitride semiconductor layer structure 350, and hence the Group III nitride material may grow upwardly from the Group III nitride semiconductor layer structure 350 to fill most of each opening 372 in the silicon nitride layer 370. However, as shown, the thin polycrystalline Group III nitride layer 362 may form around the outer edge of each opening 372.

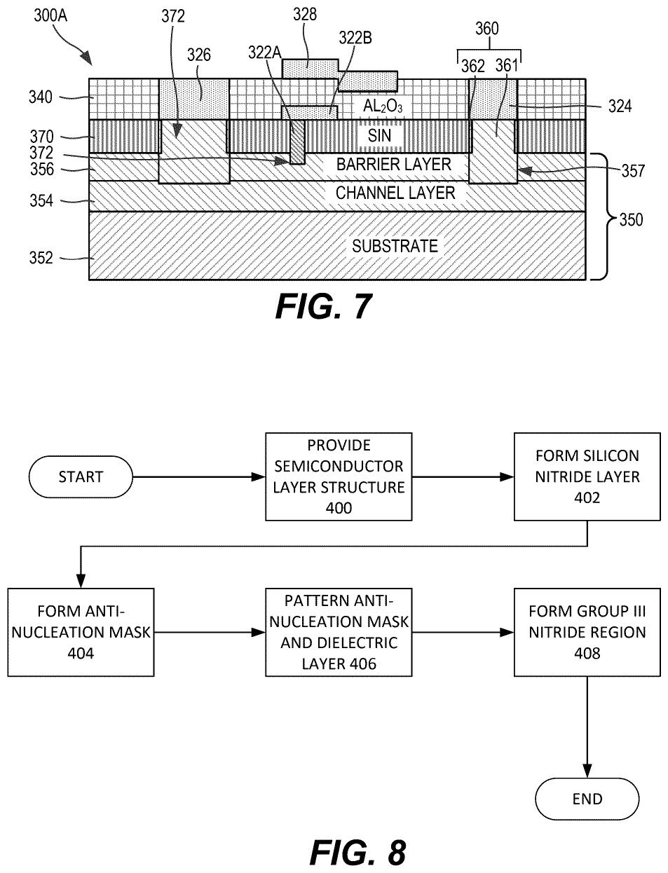

FIG. 7 is a schematic perspective cross-sectional view of a unit cell 300A of a Group III nitride RF transistor amplifier die according to further embodiments of the present invention. The unit cell 300A is similar to the unit cell 300 of FIG. 6, but further includes a regrown Group III nitride semiconductor region 322A that comprises a p-type Group III nitride region that acts as at least a portion of the gate electrode of the unit cell 300A.

As shown in FIG. 7, the regrown Group III nitride semiconductor region 322A fills an opening 372 in the silicon nitride layer 370. The regrown Group III nitride semiconductor region 322A is grown using the upper surface of the Group III nitride semiconductor layer structure 350 as a seed layer. To form an enhancement mode Group III nitride based HEMT, the gate electrode of the device may extend into the Group III nitride semiconductor layer structure 350, as shown. Accordingly, in some embodiments, a recess 357 may be formed in the upper surface of the Group III nitride semiconductor layer structure 350, and the Group III nitride semiconductor region 322A may be formed within the recess 357 and may extend upwardly from the recess 357 to fill the opening 372 in the silicon nitride layer 370. The gate electrode of unit cell 300A further comprises a second portion 322B (e.g., a metal or doped polysilicon portion) that is formed on the upper surface of the silicon nitride layer 370 and that directly contacts the Group III nitride semiconductor region 322A.

The Group III nitride semiconductor region 322A may be formed in a separate Group III nitride regrowth process than the Group III nitride semiconductor regions 360. The separate Group III nitride regrowth process may be an MBE growth process in a nitrogen plasma in some embodiments. While unit cell 300A includes both the Group III nitride semiconductor regions 360 and the Group III nitride semiconductor region 322A, it will be appreciated that in other embodiments, the Group III nitride semiconductor regions 360 may be omitted.

Thus, referring to FIG. 7, pursuant to further embodiments of the present invention, a semiconductor device 300A is provided that comprises a Group III nitride semiconductor layer structure 350 that has an upper surface that includes a plurality of recesses 357 and a plurality of Group III nitride semiconductor regions 360 in the respective recesses 357. The Group III nitride semiconductor regions 360 may protrude upwardly above the upper surface of the Group III nitride semiconductor layer structure 350 (as shown), or may be even with the upper surface of the Group III nitride semiconductor layer structure 350 or recessed below the upper surface of the Group III nitride semiconductor layer structure 350 (in which case the metal electrodes may extend into the recesses). As shown above with reference to FIG. 6, in some cases the Group III nitride semiconductor region 360 may grow upwardly from the Group III nitride semiconductor layer structure 350 to completely fill the opening 372 in the dielectric layer 370 without any nucleation occurring on the sidewalls of the opening 372 in the dielectric layer 370. However, as shown in FIG. 7, in other cases Group III nitride semiconductor material may nucleate and grow upwardly from the Group III nitride semiconductor layer structure 350 and may also nucleate on and grow from the exposed portions of the dielectric layer 370. As shown in FIG. 7, when this occurs, each Group III nitride semiconductor region 360 may include both a first portion 361 that grew upwardly from the Group III nitride semiconductor layer structure 350 and a second portion that grew from the exposed portions of the dielectric layer 370. The first portion 361 may have a first crystalline structure and the second portion 362 may have a second crystalline structure that is different from the first crystalline structure.

In some embodiments, the second crystalline structure is a polycrystalline crystal structure and the first crystalline structure is a single crystalline crystal structure. In other embodiments, the first crystalline structure is a polycrystalline crystal structure having a first average grain size and the second crystalline structure is a polycrystalline crystal structure having a second average grain size that is at least twice the first average grain size. It will be appreciated, however, that both the first portion 361 and the second portion 362 may have crystalline structures that may range anywhere from amorphous, to polycrystalline, to single crystalline depending upon a number of factors. In some embodiments, the second portion 362 may surround the first portion 361 in plan view and/or may have an annular ring shape.

FIG. 11 is a schematic perspective cross-sectional view of a unit cell 300B of a Group III nitride RF transistor amplifier die according to further embodiments of the present invention. The unit cell 300B is similar to the unit cell 300 of FIG. 6, but does not include the recesses 357 in the upper surface of the Group III nitride semiconductor layer structure 350. Consequently, the MBE Group III nitride regrowth process forms the Group III nitride semiconductor regions 360 on the top surface of the Group III nitride semiconductor layer structure 350 within the openings 372 in the dielectric layer 370. FIG. 11 illustrates that the recesses 357 may be omitted in some embodiments.

FIG. 8 is a flow chart illustrating a method of fabricating a Group III nitride RF transistor amplifier according to some embodiments of the present invention. As shown in FIG. 8, a Group III nitride semiconductor layer structure such as Group III nitride semiconductor layer structure 350 may be provided (Block 400). Then, a dielectric layer such as dielectric layer 370 may optionally be formed on an upper surface of the Group III nitride semiconductor layer structure 350 (Block 402). Next, an anti-nucleation mask layer is formed on the dielectric layer 370 opposite the Group III nitride semiconductor layer structure 350 (Block 404). The anti-nucleation mask layer and the dielectric layer are etched using a photoresist pattern as an etch mask to expose the Group III nitride semiconductor layer structure 350 (Block 406). This etching step may optionally form recesses 357 in the Group III nitride semiconductor layer structure 350. A Group III nitride semiconductor region 360 is formed (e.g., by MBE) on a portion of the Group III nitride semiconductor layer structure 350 exposed by the openings 342, 372 in the anti-nucleation mask 340 and the dielectric layer 370, respectively (Block 408). If the Group III nitride semiconductor layer structure 350 is recessed, at least a portion of the Group III nitride semiconductor region 360 may be formed within a recess 357 in the upper surface of the Group III nitride semiconductor layer structure 350.

It will be appreciated that some of the operations shown in FIG. 8 may be omitted, and/or that some of the operations shown in FIG. 8 may be formed in a different order and/or that two or more of the operations may be performed simultaneously.

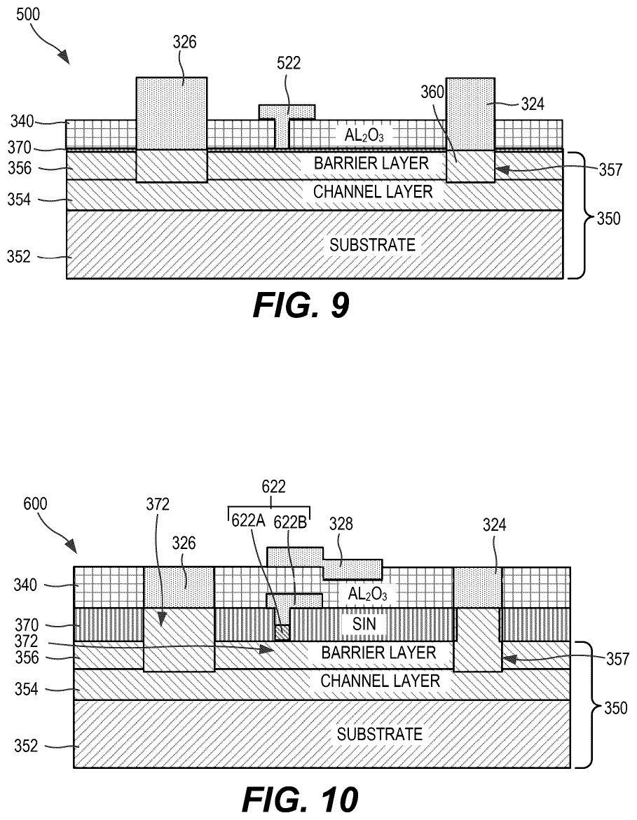

FIG. 9 is a schematic cross-sectional view of a unit cell of a Group III nitride MISHEMT power switching device 500 according to certain embodiments of the present invention. The MISHEMT 500 may have a structure that is similar to the structure of the HEMT RF transistor amplifier 300 of FIG. 6. Thus, as shown in FIG. 9, the MISHEMT 500 includes a Group III nitride semiconductor layer structure 350 that comprises a growth substrate 352, a channel layer 354 and a barrier layer 356. As these elements have been discussed above with reference to FIG. 6, further description thereof will be omitted here. A thin dielectric layer 370 (e.g., 2-5 nm thick) is formed on the upper surface of the Group III nitride semiconductor layer structure 350. The dielectric layer 370 can be formed of a wide variety of materials (e.g., silicon nitride, silicon oxide, alumina, etc.). The dielectric layer 370 may be formed in situ after the growth of the Group III nitride semiconductor layer structure 350 or may be formed after the Group III nitride semiconductor layer structure 350 is removed from the growth apparatus. An anti-nucleation layer is formed on the thin dielectric layer 370, and the anti-nucleation layer and the thin dielectric layer 370 are patterned to form an anti-nucleation mask 340 and a dielectric pattern 370 that have respective openings 342, 372 that expose the upper surface of the Group III nitride semiconductor layer structure 350 in the ohmic contact regions of the device. As these formation and patterning steps have been discussed above with reference to FIG. 6, further description thereof will be omitted here. Group III nitride semiconductor material regions 360 are then grown via, for example, MBE, in the ohmic contact regions in the manner discussed above. Drain and source electrodes 324, 326 are then formed on the Group III nitride semiconductor material regions 360. An additional opening is formed on the anti-nucleation mask 340 and a gate electrode 522 is formed in this opening (and may optionally include a portion that extends on top of the anti-nucleation mask 340, as shown). The thin dielectric layer 370 is left in place underneath the bottom surface of the gate electrode 522 so that the gate electrode 522 is separated from the Group III nitride semiconductor layer structure 350 by the thin dielectric layer 370.

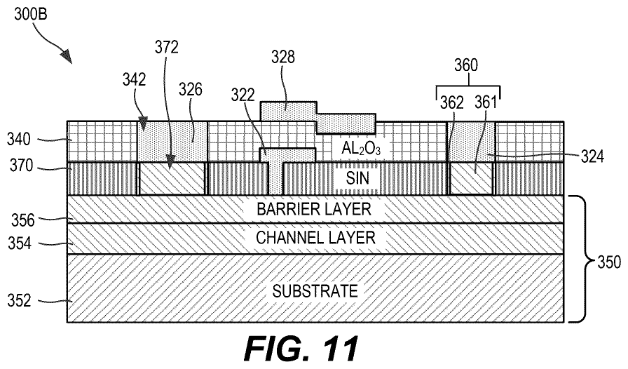

FIG. 10 is a schematic cross-sectional view of a unit cell of a Group III nitride enhancement mode power switching device 600 according to further embodiments of the present invention. The enhancement mode power switching device 600 may have a structure that is similar to the structure of the HEMT RF transistor amplifier 300 of FIG. 6, and hence the description below will only discuss the differences between the two devices. In particular, as shown in FIG. 10, the enhancement mode power switching device 600 includes a gate electrode 622 that includes a first (lower) portion 622A that is regrown within an opening in an anti-nucleation mask 340 using the above-described selective Group III nitride semiconductor regrowth techniques. The second portion 622B of the gate electrode may comprise a metal. In the depicted embodiment, the first portion 622A of the gate electrode is formed solely on top of the barrier layer 356 and is not recessed within the barrier layer 356. In other embodiments, a recess may be formed in the barrier layer 356 and the first portion of the gate electrode may be partially or completely within the recess.

It will also be appreciated that many modifications may be made to the above example embodiments without departing from the scope of the present invention. As one example, the embodiment of FIG. 6 illustrates a so-called “Ga-polar” case. In an “N-polar” case, the channel and barrier layers are inverted and the metal contacts are formed on the opposite side of the device. In such devices, the 2DEG again forms in the portion of the channel layer that is immediately adjacent the barrier layer. Thus, in an N-polar device, a recess would be formed in the Group III nitride semiconductor layer structure through the channel layer to expose the 2DEG so that Group III nitride material may be regrown that contacts the 2DEG. The recesses, however, would typically not extend into the barrier layer in this case.

Embodiments of the present inventive concepts have been described above with reference to the accompanying drawings, in which embodiments of the invention are shown.

This inventive concepts may, however, be embodied in many different forms and should not be construed as limited to the embodiments set forth herein. Rather, these embodiments are provided so that this disclosure will be thorough and complete, and will fully convey the scope of the inventive concepts to those skilled in the art. Like numbers refer to like elements throughout.

In the embodiments described above, only a few recesses are shown being formed in the Group III nitride semiconductor layer structures and only a few Group III nitride semiconductor regions are regrown in these recesses. It will be appreciated that in actual devices a large number of recesses will typically be formed with Group III nitride semiconductor regions regrown therein

It will be understood that, although the terms first, second, etc. may be used herein to describe various elements, these elements should not be limited by these terms. These terms are only used to distinguish one element from another. For example, a first element could be termed a second element, and, similarly, a second element could be termed a first element, without departing from the scope of the present invention. As used herein, the term “and/or” includes any and all combinations of one or more of the associated listed items.

The terminology used herein is for the purpose of describing particular embodiments only and is not intended to be limiting of the invention. As used herein, the terms “comprises” “comprising,” “includes” and/or “including” specify the presence of stated features, integers, steps, operations, elements, and/or components, but do not preclude the presence or addition of one or more other features, integers, steps, operations, elements, components, and/or groups thereof.

It will be understood that when an element such as a layer, region or substrate is referred to as being “on” or extending “onto” another element, it can be directly on or extend directly onto the other element or intervening elements may also be present. In contrast, when an element is referred to as being “directly on” or extending “directly onto” another element, there are no intervening elements present. It will also be understood that when an element is referred to as being “connected” or “coupled” to another element, it can be directly connected or coupled to the other element or intervening elements may be present. In contrast, when an element is referred to as being “directly connected” or “directly coupled” to another element, there are no intervening elements present.

Relative terms such as “below” or “above” or “upper” or “lower” or “horizontal” or “lateral” or “vertical” may be used herein to describe a relationship of one element, layer or region to another element, layer or region as illustrated in the figures. It will be understood that these terms are intended to encompass different orientations of the device in addition to the orientation depicted in the figures.

In the drawings and specification, there have been disclosed typical embodiments of the invention and, although specific terms are employed, they are used in a generic and descriptive sense only and not for purposes of limitation, the scope of the invention being set forth in the following claims.

1. A method of forming a semiconductor device, the method comprising:
forming an anti-nucleation mask on an upper surface of a Group III nitride semiconductor layer structure;
forming a recess in the upper surface of the Group III nitride semiconductor layer structure; and
forming a Group III nitride semiconductor region within the recess without nucleating Group III nitride semiconductor material on an exposed upper surface of the anti-nucleation mask.

2. The method of claim 1, wherein the anti-nucleation mask has an opening, and the recess is formed in a portion of the Group III nitride semiconductor layer structure that is exposed through the opening in the anti-nucleation mask.

3-4. (canceled)

5. The method of claim 1, wherein the Group III nitride semiconductor region also extends out of the recess so that an upper portion of the Group III nitride semiconductor region is above a plane defined by the upper surface of the Group III nitride semiconductor layer structure.

6. The method of claim 1, further comprising forming a dielectric layer on the upper surface of the Group III nitride semiconductor layer structure prior to forming the anti-nucleation mask.

7. The method of claim 6, wherein the dielectric layer comprises a silicon nitride layer.

8. The method of claim 6, wherein the dielectric layer includes an opening that vertically overlaps the opening in the anti-nucleation mask, and wherein the Group III nitride semiconductor region extends into the opening in the dielectric layer.

9. (canceled)

10. The method of claim 1, wherein the semiconductor device comprises a Group III nitride RF transistor amplifier that includes a plurality of gate electrodes, a plurality of drain electrodes and a plurality of source electrodes.

11. The method of claim 10, wherein the Group III nitride semiconductor region is positioned underneath and contacts one of drain electrodes or one of the source electrodes.

12. (canceled)

13. The method of claim 10, wherein the Group III nitride RF transistor amplifier further includes a field plate, and wherein the anti-nucleation mask electrically insulates the field plate from a first of the gate electrodes.

14. A method of forming a Group III nitride RF transistor amplifier, the method comprising:
forming an anti-nucleation mask on an upper surface of a Group III nitride semiconductor layer structure, the anti-nucleation mask having an opening; and
forming a Group III nitride semiconductor region on a portion of the Group III nitride semiconductor layer structure exposed by the opening in the anti-nucleation mask.

15. The method of claim 14, wherein at least a portion of the Group III nitride semiconductor region is formed within a recess in the upper surface of the Group III nitride semiconductor layer structure.

16. The method of claim 14, wherein the Group III nitride semiconductor region is formed by molecular beam epitaxy.

17. The method of claim 16, wherein an upper surface of the anti-nucleation mask is exposed during the forming of the Group III nitride semiconductor region, and wherein Group III nitride semiconductor material does not nucleate on the anti-nucleation mask during the formation of the Group III nitride semiconductor region.

18. The method of claim 16, wherein the anti-nucleation mask comprises an alumina mask, and an upper surface of the anti-nucleation mask is exposed during the forming of the Group III nitride semiconductor region.

19. The method of claim 16, further comprising forming a silicon nitride layer on the upper surface of the Group III nitride semiconductor layer structure prior to forming the anti-nucleation mask.

20. The method of claim 19, wherein the silicon nitride layer includes an opening that vertically overlaps the opening in the anti-nucleation mask, and wherein the Group III nitride semiconductor region extends into the opening in the silicon nitride layer.

21. The method of claim 14, wherein a first portion of the Group III nitride semiconductor region has a first molar composition and horizontally overlaps a portion of the Group III nitride semiconductor layer structure that has a second molar composition that is different from the first molar composition.

22. (canceled)

23. The method of claim 14, wherein the Group III nitride semiconductor region comprises at least part of the gate electrode.

24. (canceled)

25. The method of claim 14, wherein forming the Group III nitride semiconductor region within the recess comprises forming the Group III nitride semiconductor region within the recess in a manner such that Group III nitride semiconductor material does not nucleate on an exposed upper surface of the anti-nucleation mask.

26-64. (canceled)

65. The method of claim 1, wherein the anti-nucleation mask is a GaN/InGaN anti-nucleation mask.

66-67. (canceled)
